(19) United States
(12) Patent Application Publication
(10) Pub. No.: US 2024/0249964 A1
(43) Pub. Date: Jul. 25, 2024

(54) SUBSTRATE PROCESSING SYSTEM AND SUBSTRATE PROCESSING METHOD

(71) Applicant: Tokyo Electron Limited, Tokyo (JP)

(72) Inventors: Shinsuke TAKAKI, Koshi City (JP); Seiji NAKASHIMA, Koshi City (JP); Akihiro TERAMOTO, Koshi City (JP); Ryo SHOBU, Koshi City (JP)

(21) Appl. No.: 18/417,564

(22) Filed: Jan. 19, 2024

(30) Foreign Application Priority Data
Jan. 20, 2023 (JP) 2023-007600

(51) Int. Cl. H01L 21/677; H01L 21/67; H01L 21/673

(52) U.S. Cl. CPC H01L 21/67736; H01L 21/67161; H01L 21/67225; H01L 21/67389; H01L 21/6773

(57) ABSTRACT

A substrate processing system that performs substrate processing includes: a first processing system having one of a wet processing apparatus and a dry processing apparatus; a second processing system having the other one of the wet processing apparatus and the dry processing apparatus, wherein the first processing system includes a common stage, which is common to the first processing system and the second processing system and is configured to place thereon a container accommodating substrates before being subjected to the substrate processing, wherein the substrate processing system further includes: a first transfer system configured to transfer the substrates between the first processing system and the second processing system; and a second transfer system connected to at least the second processing system, and configured to transfer the substrates between the first processing system and the second processing system, or between another stage and the second processing system.

### CROSS-REFERENCE TO RELATED APPLICATION

This application is based upon and claims the benefit of priority from Japanese Patent Application No. 2023-007600, filed on Jan. 20, 2023, the entire contents of which are incorporated herein by reference.

### TECHNICAL FIELD

The present disclosure relates to a substrate processing system and a substrate processing method.

### BACKGROUND

Patent Document 1 discloses a substrate processing system including: a processing station in which a plurality of processing units for processing substrates are provided in multiple stages in a vertical direction; a cassette platform on which a cassette that accommodates a plurality of substrates is placed; and a substrate transfer mechanism disposed between the processing station and the cassette platform. Between the processing station and the substrate transfer mechanism, a plurality of delivery units are provided in multiple stages to temporarily accommodate substrates transferred between the cassette platform and the processing station, and substrates transferred between respective stages of the processing units. In addition, the substrate transfer mechanism also includes a first transfer arm that transfers the substrates between the cassette platform and each delivery unit, and a second transfer arm that transfers the substrates between respective stages of the delivery units.

### PRIOR ART DOCUMENT

### Patent Document

Patent Document 1: Japanese Patent Laid-Open Publication No. 2013-69874

### SUMMARY

One embodiment of the present disclosure provides a substrate processing system that performs substrate processing, wherein the substrate processing includes at least one of forming a resist film on a substrate or developing the resist film after exposure, the substrate processing system including: a first processing system having one of a wet processing apparatus configured to perform the substrate processing in a wet manner and a dry processing apparatus configured to perform the substrate processing in a dry manner; and a second processing system having the other one of the wet processing apparatus and the dry processing apparatus, wherein the first processing system includes a common stage that is common to the first processing system and the second processing system, wherein the common stage is configured to place a container, which is configured to accommodate a plurality of substrates before being subjected to the substrate processing, on the common stage, wherein the substrate processing system further includes: a first transfer system configured to transfer the substrates between the first processing system and the second processing system; and a second transfer system provided separately from the first transfer system and connected to at least the second processing system, and wherein the second transfer system is configured to transfer the substrates between the first processing system and the second processing system, or between another stage, which is provided separately from the common stage and on which the container is placed, and the second processing system.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is an explanatory view schematically illustrating an internal configuration of a wafer processing system as a substrate processing system according to a first embodiment.

FIG. 2 is a view schematically illustrating an internal configuration on a front side of a wet processing system.

FIG. 3 is a view schematically illustrating an internal configuration on a rear side of the wet processing system.

FIG. 4 is a view schematically illustrating a cross section of the wafer processing system of FIG. 1 at an interface station portion.

FIG. 5 is a view illustrating another example of a stage different from a common stage.

FIG. 6 is a view illustrating another example of a first transfer system.

FIG. 7 is a view illustrating another example of the wet processing system and a second transfer system.

FIG. 8 is a view illustrating another example of the second transfer system.

FIG. 9 is a view illustrating another example of a dry processing system.

FIG. 10 is an explanatory view schematically illustrating an internal configuration of a wafer processing system as a substrate processing system according to a second embodiment.

FIG. 11 is an explanatory view schematically illustrating an internal configuration of a wafer processing system as a substrate processing system according to a third embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In photolithography in a manufacturing process of semiconductor devices or the like, a series of processes is performed to form a desired resist pattern on a substrate such as a semiconductor wafer (hereinafter, referred to as a “wafer”). The above-mentioned series of processes, i.e., processes for photolithography, include, for example, a resist film formation process to form a resist film on the substrate, an exposure process to expose the resist film, a development process to develop the exposed resist film, and the like. Among these processes for photolithography, processes other than the exposure process, for example, the development process, may be performed by using a liquid, i.e., in a wet manner, or may be performed by using a gas, i.e., in a dry manner.

According to a type of a resist, a resist pattern with a desired shape may be obtained only by a wet development process or only by a dry development process. However, when a wet processing system that performs the wet development process and a dry processing system that performs the dry development process are provided separately, these systems will occupy a large amount of space. The same applies to the resist film formation process, because the resist film formation process may be performed in both wet and dry manners.

Therefore, the technology according to the present disclosure makes it possible to perform the processes for photolithography other than the exposure process in both wet and dry manners in a relatively small space.

Hereinafter, a substrate processing system and a substrate processing method according to the present embodiment will be described with reference to the drawings. In the specification and drawings, elements having substantially the same functional configurations will be denoted by the same reference numerals and redundant descriptions will be omitted.

### First Embodiment

### <Wafer Processing System>

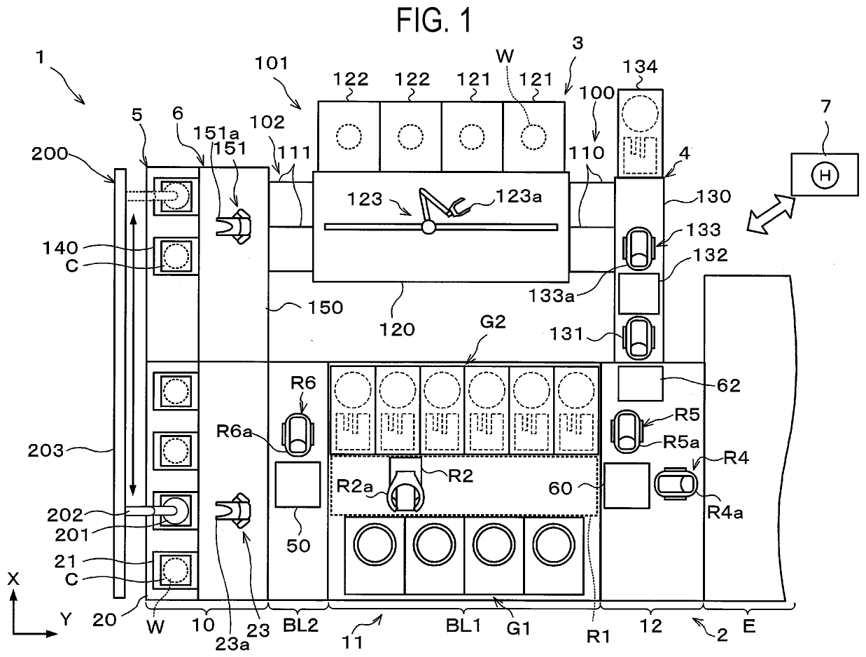

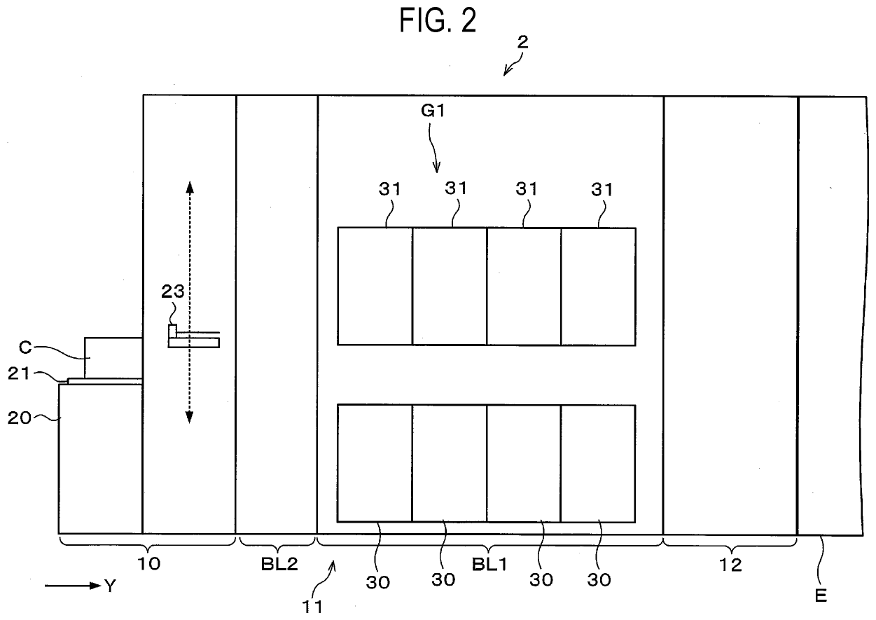

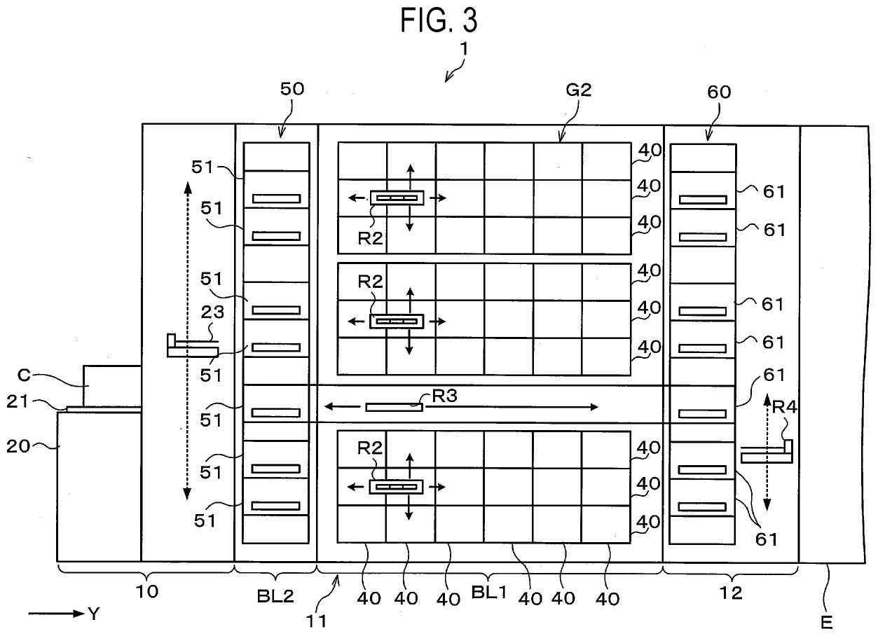

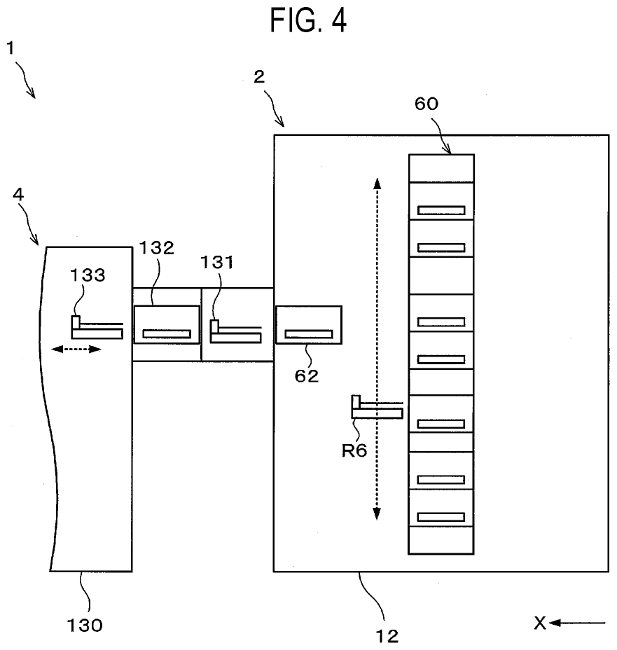

FIG. 1 is an explanatory view schematically illustrating an internal configuration of a wafer processing system as a substrate processing system according to a first embodiment. FIGS. 2 and 3 are views schematically illustrating internal configurations of front and rear sides of the wet processing system, respectively, which will be described later. FIG. 4 is a view schematically illustrating a cross section of the wafer processing system of FIG. 1 at an interface station portion, which will be described later.

A wafer processing system 1 in FIG. 1 includes a wet processing system 2 as a first processing system, a dry processing system 3 as a second processing system, a first transfer system 4, a stage 5, and a second transfer system 6.

As illustrated in FIGS. 1 to 3, the wet processing system 2 includes a cassette station 10, a processing station 11, and an interface station 12 as an interface block, and is connected to an exposure apparatus E. The exposure apparatus E performs an exposure process on a wafer W as a substrate, in particular, performs the exposure process on the wafer W by using, for example, extreme ultraviolet (EUV) light. In the wet processing system 2, the cassette station 10, the processing station 11, and the interface station 12 are integrally connected to one another. The wet processing system 2 also includes a cassette transfer apparatus 200, which will be described later.

Hereinafter, a direction in which the wet processing system 2 and the exposure apparatus E are connected to each other will be referred to as a width direction, and a direction perpendicular to the aforementioned connection direction, i.e., the width direction, when viewed from above, will be referred to as a depth direction.

The cassette station 10 of the wet processing system 2 serves to load and unload a cassette C, which is a container configured to accommodate a plurality of wafers W.

The cassette station 10 is provided with a stage 20 on which cassettes C are placed, for example, at an end on a first side in the width direction (a negative side in a Y direction in the figure). A plurality of (e.g., four) placement plates 21 are provided on the stage 20. The placement plates 21 are arranged in a row in the depth direction (an X direction in the figure). The cassettes C may be placed on these placement plates 21. In addition, in one embodiment, the cassette transfer apparatus 200 as a container transfer apparatus that transfers the cassette Cis accessible to the stage 20. Specifically, it is possible for the cassette transfer apparatus 200 either to place the cassette C on the placement plate 21 or to remove the cassette C from the stage 20, without covering a top of the stage 20. The cassette transfer apparatus 200 includes, for example, an articulated arm 202 having a holder 201 at its tip to hold the cassette C, and a rail 203 supporting the articulated arm 202 to be movable in the depth direction (the X direction in the figure). The articulated arm 202 is supported by the rail 203 to be movable in a vertical direction as well.

In addition, the cassette station 10 is provided with a transfer apparatus 23 that transfers the wafer W, for example, on a second side in the width direction (a positive side in the Y direction in the figure). The transfer apparatus 23 has a transfer arm 23a configured to be movable in the depth direction (the X direction in the figure). In addition, the transfer arm 23a of the transfer apparatus 23 is configured to be movable vertically and around a vertical axis.

The transfer apparatus 23 can hold the wafer W on the transfer arm 23a and transfer the wafer W between the cassette C on each placement plate 21 and a delivery apparatus 51 of a delivery tower 50, which will be described later.

In addition, the cassette station 10 may be provided with a storage (not illustrated) in which the cassettes C are placed and stored, at a location above the stage 20 or a location farther from the exposure apparatus E than the stage 20 (a location on the negative side in the Y direction in the figure).

The processing station 11 includes a plurality of various processing apparatuses, each of which performs a predetermined process such as the resist film formation process.

The processing station 11 is divided into a plurality of blocks (two in the illustrated example), each of which includes various apparatuses. A processing block BL1 is provided on a side of the interface station 12, and a delivery block BL2 is provided on a side of the cassette station 10.

The processing block BL1 has, for example, a first block G1 on a front side (a negative side in the X direction in the figure) and a second block G2 on a rear side (a positive side in the X direction in the figure).

In the first block G1, for example, as illustrated in FIG. 2, a plurality of liquid processing apparatuses, for example, a development apparatus 30 that performs the development process on the wafer W, and a resist coating apparatus 31 that performs the resist film formation process on the wafer W are arranged in that order from below. The development apparatus 30 is an example of the wet processing apparatus. The wet processing apparatus performs wafer processing as any substrate processing from forming the resist film on the wafer W to developing the resist film after exposure, i.e., any wafer processing among the processes for photolithography, in a wet manner.

For example, four development apparatuses 30 and four resist coating apparatuses 31 are arranged side by side in the width direction (the Y direction in the figure). In addition, the number and arrangement of the development apparatuses 30 and resist coating apparatuses 31 may be arbitrarily selected.

In the development apparatuses 30 and the resist coating apparatuses 31, predetermined processing liquids are applied onto the wafer W by using, for example, a spin coating method. In the spin coating method, for example, a processing liquid is ejected from an ejection nozzle onto the wafer W, and the wafer W is rotated to spread the processing liquid on a surface of the wafer W.

For example, in the second block G2, as illustrated in FIG. 3, a plurality of heat treatment apparatuses 40, which perform heat treatment such as heating or cooling the wafer W, is arranged in the vertical direction (the vertical direction in the figure) and the width direction (the Y direction in the figure). The number and arrangement of the heat treatment apparatuses 40 may be arbitrarily selected.

In the wet processing system 2, the development apparatuses 30, the resist coating apparatuses 31, and the heat treatment apparatuses 40 process the wafer W, for example, in a sheet-by-sheet manner.

In addition, as illustrated in FIG. 1, the processing block BL1 is provided with a transfer region R1 extending in the width direction between the first block G1 and the second block G2. In the processing block BL1, the development apparatuses 30 and the resist coating apparatuses 31 are disposed to be aligned along the transfer region R1 extending in the width direction. In the transfer region R1, a transfer apparatus R2 that transfers the wafer W is disposed.

The transfer apparatus R2 has a transfer arm R2a that is movable, for example, in the width direction (the Y direction in the figure), vertically, and around the vertical axis. The transfer apparatus R2 can move the transfer arm R2a holding the wafer W within the transfer region R1 and transfer the wafer W to a predetermined apparatus in the surrounding first block G1, second block G2, delivery towers 50 and 60, which will be described later. As illustrated in FIG. 3, a plurality of transfer apparatuses R2 is disposed vertically, for example, and each transfer apparatus R2 can transfer the wafer W to a predetermined apparatus having approximately the same height in the first block G1, the second block G2, and the delivery towers 50 and 60, for example.

In addition, in the transfer region R1, a shuttle transfer apparatus R3 is provided to linearly transfer the wafer W between the delivery tower 50 and the delivery tower 60.

The shuttle transfer apparatus R3 can linearly move the wafer W supported thereon in the width direction (the Y direction in the figure) and transfer the wafer W between an apparatus in the delivery tower 50 and an apparatus in the delivery tower 60, which have approximately the same height.

As illustrated in FIG. 1, the delivery block BL2 is provided with the delivery tower 50 at a center portion thereof in the depth direction (the X direction in the figure). Specifically, the delivery tower 50 is provided in the delivery block BL2 at a position adjacent to the transfer region R1 of the processing block BL1 in the width direction (the Y direction in the figure). As illustrated in FIG. 3, a plurality of delivery apparatuses 51 is provided in the delivery tower 50 to overlap with one another in the vertical direction.

As illustrated in FIG. 1, the interface station 12 is provided between the processing block BL1 of the processing station 11 and the exposure apparatus E and delivers the wafer W therebetween.

The delivery tower 60 is provided in the interface station 12 at a position adjacent to the transfer region R1 of the processing block BL1 in the width direction (the Y direction in the figure). As illustrated in FIG. 3, a plurality of delivery apparatuses 61 is provided in the delivery tower 60 to overlap with one another in the vertical direction.

In addition, as illustrated in FIG. 1, a delivery apparatus 62 is provided on the rear side (the positive side in the X direction in the figure) of the interface station 12.

In addition, the interface station 12 is provided with transfer apparatuses R4 and R5.

The transfer apparatus R4 is provided at a position adjacent to the delivery tower 60 in the width direction (the Y direction in the figure), and includes, for example, a transfer arm R4a that is movable in the depth direction (the X direction in the figure), vertically, and around the vertical axis. The transfer apparatus R4 can hold the wafer W on the transfer arm R4a and transfer the wafer W between the plurality of delivery apparatuses 61 in the delivery tower 60 and the exposure apparatus E.

The transfer apparatus R5 is provided between the delivery tower 60 and the delivery apparatus 62 and includes, for example, a transfer arm R5a that is movable vertically and around the vertical axis. The transfer apparatus R5 can hold the wafer W on the transfer arm R5a and transfer the wafer W between the plurality of delivery apparatuses 61 in the delivery tower 60 and the delivery apparatus 62.

In addition, the delivery block BL2 is provided with a transfer apparatus R6. The transfer apparatus R6 is provided on the rear side (the positive side in the X direction in the figure) of the delivery tower 50 and includes a transfer arm R6a which is movable vertically and around the vertical axis. The transfer apparatus R6 can hold the wafer W on the transfer arm R6a and transfer the wafer W between the plurality of delivery apparatuses 51 in the delivery tower 50.

The dry processing system 3 includes a first load-lock station 100, a processing station 101, and a second load-lock station 102. In the dry processing system 3, the load-lock station 100, the processing station 101, and the second load-lock station are aligned in that order along the width direction (the Y direction in the figure) and are integrally connected to one another.

The first and second load-lock stations 100 and 102 are respectively provided with load-lock apparatuses 110 and 111 configured to be capable of switching an internal atmosphere between a reduced pressure atmosphere and atmospheric pressure atmosphere.

The processing station 101 includes a vacuum transfer chamber 120, a processing apparatus 121, and a post-processing apparatus 122.

The vacuum transfer chamber 120 is configured as a hermetically sealed housing, and an interior thereof is maintained to be in a reduced pressure state (vacuum state). The vacuum transfer chamber 120 is formed, for example, in a rectangular shape when viewed from above.

For example, a plurality of (two in the illustrated example) processing apparatuses 121 and a plurality of (two in the illustrated example) post-processing apparatuses 122 are provided in the processing station 101. The processing apparatuses 121 provided in the processing station 101 are dry processing apparatuses and perform the same type of wafer processing as the wet processing apparatuses of the wet processing system 2, specifically the development process performed by the development apparatuses 30, in a dry manner. The dry manner is a manner using a gas, specifically, a manner using a gas under a reduced pressure. It may also be said that dry processing obtains its intended effect mainly with a gas, while wet processing obtains its effect mainly with a liquid.

The post-processing apparatuses 122 perform heat treatment as post-processing on the wafer W after the dry development process. Thus, it is possible to remove the gas for the dry development process that has adhered to the wafer W, and further, to remove reaction products that have adhered to the wafer W during the dry development process.

The processing apparatuses 121 and the post-processing apparatuses 122 process the wafer W, for example, in a sheet-by-sheet manner.

In the processing station 101, the processing apparatuses 121 and the post-processing apparatuses 122 are disposed to be aligned in the width direction (the Y direction in the figure).

In addition, a transfer apparatus 123 that transfers the wafer W is provided inside the vacuum transfer chamber 120. The transfer apparatus 123 has a transfer arm 123a that is movable, for example, in the width direction (the Y direction in the figure) and around the vertical axis. The transfer apparatus 123 can hold the wafer W on the transfer arm 123a and transfer the wafer W among the processing apparatuses 121, the post-processing apparatuses 122, and the load-lock apparatuses 110 and 111.

The first transfer system 4 transfers the wafer W between the wet processing system 2 and the dry processing system 3, in particular, transfers the wafer W in a wafer unit, that is, in a sheet-by-sheet manner.

The first transfer system 4 has a transfer path 130 at a position adjacent to the interface station 12 in the depth direction (the X direction in the figure). Specifically, the first transfer system 4 has the transfer path 130 at a position adjacent to the delivery apparatus 62 of the interface station 12 in the depth direction. A side of the transfer path 130 opposite to the delivery apparatus 62 in the depth direction is connected to the dry processing system 3, in particular, connected to the first load-lock station 100. The transfer path 130 is maintained at the same pressure as an interior of the wet processing system 2. The term “same pressure” here does not mean exactly the same pressure, and it is sufficient that the pressure in the transfer path 130 is closer to the pressure inside the wet processing system 2 than the pressure inside the dry processing system 3. In addition, the transfer path 130 is maintained to have the same atmosphere as that of the wet processing system 2. The term “same atmosphere” here does not mean exactly the same atmosphere, and it is sufficient that the atmosphere inside the transfer path 130 is closer to the atmosphere inside the wet processing system 2 than the atmosphere inside the dry processing system 3.

In the transfer path 130, a shuttle transfer apparatus 131, a delivery apparatus 132, and a transfer apparatus 133 are provided in that order from a side of the interface station 12 along the depth direction (the X direction in the figure) when viewed from above.

The shuttle transfer apparatus 131 and the delivery apparatus 132 are provided at the same height as the delivery apparatus 62 of the interface station 12, as illustrated in FIG. 4.

The shuttle transfer apparatus 131 transfers wafers W between the delivery apparatus 132 and the delivery apparatus 62.

As illustrated in FIG. 1, the transfer apparatus 133 has a transfer arm 133a that is movable, for example, in the depth direction (the X direction in the figure), vertically, and around the vertical axis. The transfer apparatus 133 can hold the wafer W on the transfer arm 133a and transfer the wafer W between the delivery apparatus 132 and the load-lock apparatus 110 of the dry processing system 3.

In addition, the first transfer system 4 may be provided with a heat treatment apparatus 134 similar to the heat treatment apparatuses 40. A plurality of heat treatment apparatuses 134 may be provided.

A stage 5 is provided separately from the stage 20 of the wet processing system 2, and similar to the stage 20, cassettes C are placed on the stage 5. The stage 5 is provided, for example, at a position adjacent to the stage 20 in the depth direction (the X direction in the figure). For example, two placement plates 140 are provided on the stage 5. The placement plates 140 are arranged side by side in the depth direction (the X direction in the figure). The cassettes C can be placed on the placement plates 140. In an example, the stage 5 is accessible by the cassette transfer apparatus 200. Specifically, it is possible for the cassette transfer apparatus 200 either to place the cassette C on the placement plate 140 or to remove the cassette C from the stage 5, without covering portions on which the cassettes C are placed in the stage 5.

In one embodiment, the second transfer system 6 transfers the wafer W between the dry processing system 3 and the stage 5, in particular, transfers the wafer W in a wafer unit, that is, in a sheet-by-sheet manner.

The second transfer system 6 has a transfer path 150 at a position adjacent to the stage 5 in the width direction (the Y direction in the figure). A side of the transfer path 150 opposite to the stage 5 in the width direction is connected to the dry processing system 3, in particular, connected to the second load-lock station 102. Like the transfer path 130 of the first transfer system 4, the transfer path 150 is maintained at the same pressure and the same atmosphere as the interior of the wet processing system 2.

The transfer path 150 is provided with a transfer apparatus 151 that transfers the wafer W. The transfer apparatus 151 has a transfer arm 151a configured to be movable in the depth direction (the X direction in the figure). In addition, the transfer arm 151a of the transfer apparatus 151 is configured to be movable vertically and around the vertical axis. The transfer apparatus 151 can transfer the wafer W between the cassettes C on respective placement plates 140 and the load-lock apparatus 111 of the dry processing system 3.

In addition, the wafer processing system 1 includes a control device 7 that controls the wafer processing system 1 including controlling the transfer apparatuses. The control device 7 is, for example, a computer including a processor such as a CPU, and memory, and has a program storage (not illustrated). The program storage stores a program including commands for controlling operations of drive systems of the various processing apparatuses and various transfer apparatuses described above and controlling the processes performed by the wafer processing system 1, which will be described later. The program may be recorded in a computer-readable storage medium H, and may be installed on the control device 7 from the storage medium H. The storage medium H may be transitory or non-transitory.

### Processing Example 1 by Wafer Processing System 1

Next, a processing example by the wafer processing system 1 will be described.

In the processing by the wafer processing system 1, the wafer W is selectively transferred to either the development apparatus 30 that performs the wet development process or the processing apparatus 121 that performs the dry development process.

In the present example, the development process is performed once on one wafer W, and only one of the wet development process and the dry development process is performed. That is, the wafer W is transferred to only one of the development apparatuses 30 that perform the wet development process and the processing apparatuses 121 that perform the dry development process.

When only the wet development process is performed, the dry processing system 3 of the wafer processing system 1 is not used, and only the wet processing system 2 is used. On the other hand, when only the dry development process is performed, for example, processes (excluding the exposure process) up to the development process among the processes for photolithography are performed in the wet processing system 2, and then the wafer W is transferred to the dry processing system 3 via a transfer by the transfer system 4 and is subjected to the dry development process.

Hereinafter, a more detailed description will be given.

In the wafer processing using the wafer processing system 1, regardless of whether the wet development process or the dry development process is performed, the wafer W is first taken out from the cassette C on the stage 20 by the transfer apparatus 23 of the wet processing system 2 and is transferred to the delivery apparatus 51 of the delivery tower 50 of the delivery block BL2.

Subsequently, the wafer W is transferred by the transfer apparatus R2 to the heat treatment apparatus 40 of the processing block BL1 and is subjected to a temperature adjustment process. Thereafter, the wafer W is transferred to the resist coating apparatus 31, and the resist film is formed on the wafer W. Specifically, for example, a film of a metal-containing resist is formed on the wafer W. The metal contained in the metal-containing resist is, for example, tin. Subsequently, the wafer W is transferred to the heat treatment apparatus 40 and is subjected to a pre-applied bake (PAB) process. In addition, similar heat treatments are performed in the pre-bake process, a subsequent post exposure bake (PEB) process, and a post bake process. However, the heat treatment apparatuses 40 provided for the respective heat treatments are different from one another.

Subsequently, the wafer W is transferred to the delivery apparatus 61 of the delivery tower 60 of the interface station 12. Subsequently, the wafer W is transferred to the exposure apparatus E by the transfer apparatus R4 and is subjected to the exposure process using extreme ultraviolet (EUV) light.

After the exposure, the wafer W is transferred to the delivery apparatus 61 of the delivery tower 60 by the transfer apparatus R4. Subsequently, the wafer W is transferred to the heat treatment apparatus 40 by the transfer apparatus R2 and is subjected to the PEB process.

Thereafter, the wafer W is subjected to either the wet development process or the dry development process.

When the wet development process is performed, for example, the wafer W after the PEB process is transferred to the development apparatus 30 by the transfer apparatus R2. After the wet development process is performed by the development apparatus 30, the wafer W is transferred to the heat treatment apparatus 40 and is subjected to the post bake process. Thereafter, the wafer W is transferred to the delivery apparatus 51 of the delivery tower 50 of the delivery block BL2. Then, the wafer W is returned to the cassette C on the stage 20 by the transfer apparatus 23.

On the other hand, when the dry development process is performed, for example, the wafer W after the PEB process is transferred to the delivery apparatus 61 of the delivery tower 50 of the interface station 12 by the transfer apparatus R2. Subsequently, the wafer W is transferred to the delivery apparatus 62 by the transfer apparatus R5. Subsequently, the wafer W is transferred to the delivery apparatus 132 by the shuttle transfer apparatus 131 of the first transfer system 4. Subsequently, the wafer W is transferred to the load-lock apparatus 110 of the dry processing system 3 by the transfer apparatus 133. Thereafter, after the pressure inside the load-lock apparatus 110 is reduced, the wafer W is transferred to the processing apparatus 121 by the transfer apparatus 123. After the dry development process is performed by the processing apparatus 121, the wafer W is transferred to the post-processing apparatus 122 and is subjected to a heat treatment. After the heat treatment, the wafer W is transferred to the load-lock apparatus 111. After the interior of the load-lock apparatus 111 is set to atmospheric pressure atmosphere, the wafer W is returned to the cassette C on the stage 5 by the transfer apparatus 151 of the second transfer system 6.

### Processing Example 2 by Wafer Processing System 1

In the above-described Processing Example 1, the development process was performed on the wafer W once, and either the wet development process or the dry development process was performed on the wafer W. In the wafer processing using the wafer processing system 1, the development process may be performed on the wafer W multiple times, and in that case, both the wet development process and the dry development process may be performed on the wafer W.

For example, when the development process is performed twice, the wet development process may be performed first and the dry development process may be performed next, or vice versa. In this case, heat treatment may be performed at least one of before the first development process, between the first development process and the second development process (i.e., between the wet development process and the dry development process), or after the second development process.

Specifically, in the wafer processing system 1, the wafer W may be transferred to an apparatus corresponding to the first development process, subjected to either the wet development process or the dry development process, then transferred to an apparatus corresponding the second development process by the first transfer system 4, and subjected to the remaining one of the wet development process and the dry development process. In this case, the heat treatment may be performed in the heat treatment apparatus 40 of the wet processing system 2 at least one of between the wet development process and the dry development process in the first development process or after the second development process. Whether or not to perform this heat treatment may be determined according to the purpose.

### <Modifications of Processing Examples 1 and 2 by Wafer Processing System 1>

In Processing Examples 1 and 2 by the wafer processing system 1, the heat treatment performed in the heat treatment apparatus 40 of the wet processing system 2 (e.g., the heat treatment immediately before the dry development process, i.e., the PEB process) may be performed in the heat treatment apparatus 134 of the first transfer system 4. With this configuration, it is possible to omit transferring the wafer W after the PEB process and before the dry development process by the transfer apparatus R2, thereby reducing an operation rate of the transfer apparatus R2.

### <Main Effects of the Present Embodiment>

In the present embodiment, as described above, the wafer processing system 1 includes the wet processing system 2 having the development apparatus 30 that performs the wet development process, and the dry processing system 3 having the processing apparatus 121 that performs the dry development process. In addition, the wet processing system 2 includes the stage 20, on which the cassettes C are placed and which is common to the wet processing system 2 and the dry processing system 3. In addition, the wafer processing system 1 includes the first transfer system 4 that transfers the wafer W between the wet processing system 2 and the dry processing system 3, and the second transfer system 6 that is provided separately from the first transfer system 4. In addition, the second transfer system 6 transfers the wafer W between the dry processing system 3 and the stage 5 that is provided separately from the common stage 20. With this configuration, in the wafer processing system 1, the wafer W is loaded into the wafer processing system 1 from the common stage 20 is selectively transferred to the development apparatus 30 that performs the wet development process or the processing apparatus 121 that performs the dry development process so that the development process can be performed in the corresponding apparatus.

That is, in the wafer processing system 1, the wet development process and the dry development process can be performed without providing the wet processing system 2 and the dry processing system 3 separately as completely different systems. Instead, the wet processing system 2 and the dry processing system 3 are connected to each other by the first transfer system 4, and the wet processing system 2 and the dry processing system 3 share the stage 20 on which the cassettes C accommodating the wafers W to be processed are placed, or the like. Therefore, according to the present embodiment, both the wet and dry development processes can be performed in a smaller space compared to the case where the wet processing system 2 and the dry processing system 3 are provided separately as completely different systems.

In addition, since the wet processing system 2 and the dry processing system 3 are connected to each other to form an internal space of the wafer processing system 1 separated from an external space, in either case of processing the wafer W by the wet processing system 2 or the dry processing system 3, an atmosphere in a space where the wafer W is transferred and processed can be easily controlled. The atmosphere control mentioned here includes controlling, for example, a temperature, a humidity, components of a gas supplied to a target space by a filter, or the like, but is not limited thereto.

In addition, in the present embodiment, regardless whether processes for wet photolithography or processes for dry photolithography are performed as the series of processes for forming the resist pattern including the exposure process, the wafer W is processed in an in-line manner. That is, the wafer W, which is taken out from the cassette C loaded into the wafer processing system 1, is not unloaded to the outside of the wafer processing system 1 until the wafer W is subjected to the above series of processes and then returned to the cassette C for unloading to the outside of the wafer processing system 1. In order to implement such in-line processing, the control device 7 manages a timing to start transferring the wafer W for the series of processes, a timing to complete each process included in the above series of processes, a timing to return the wafer W to the cassette C, and the like. Therefore, regardless of whether the above series of processes includes any of the processes for wet photolithography and the processes for dry photolithography, the control device 7 can easily recognize a status of each process included in the above series of processes and adjust a transfer timing.

In addition, in the present embodiment, the transfer path 130 of the first transfer system 4 has a first end connected to the dry processing system 3, and a second end connected to the exposure apparatus E via the wet processing system E, rather than being directly connected to the wet processing system 2. For example, as illustrated in FIG. 1, the first end of the transfer path 130 of the first transfer system 4 is connected to the interface station 12, which is a part of the wet processing system 2 and has an internal space having a lower pressure than a space for loading/unloading of the exposure apparatus E. That is, the dry processing system 3 and the exposure apparatus E are connected to each other via a part of the wet processing system 2 that is under a negative pressure with respect to the exposure apparatus E. Since a corrosive gas may be used in the dry processing system 3 for the dry development process or the like, by connecting the dry processing system 3 and the exposure apparatus E to each other as described above, it is possible to suppress the corrosive gas from entering the exposure apparatus E.

<Another Example of Stage Different from Common Stage 20>

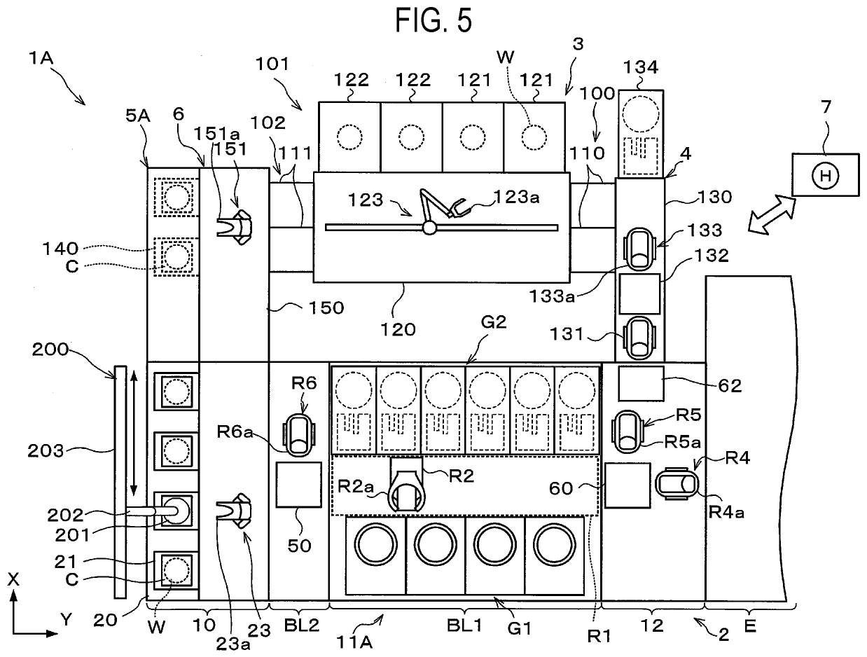

FIG. 5 is a view illustrating another example of a stage different from the common stage 20.

The stage 5, which is different from the common stage 20 as illustrated in FIG. 1 and the like, is accessible by the cassette transfer apparatus 200 without being covered in a portion where the cassette C is placed. Alternatively, as illustrated in FIG. 5, a stage 5A, which is different from the common stage 20, is covered in a portion where the cassette C is placed, and is spaced apart from the stage 20 so that the cassette transfer apparatus 200 is not accessible to the stage 5A. By using the stage 5A in a wafer processing system 1A, even when a corrosive gas is used in the dry development process, it is possible to suppress the corrosive gas from leaking from the wafers W accommodated in the cassette C on the stage 5A to the outside of the wafer processing system 1A. In this example, in the cassette transfer apparatus 200, the rail 203 is formed short and does not reach the stage 5A, so that the articulated arm 202 only accesses the stage 20 without accessing the stage 5A.

### <Other Examples of First Transfer System>

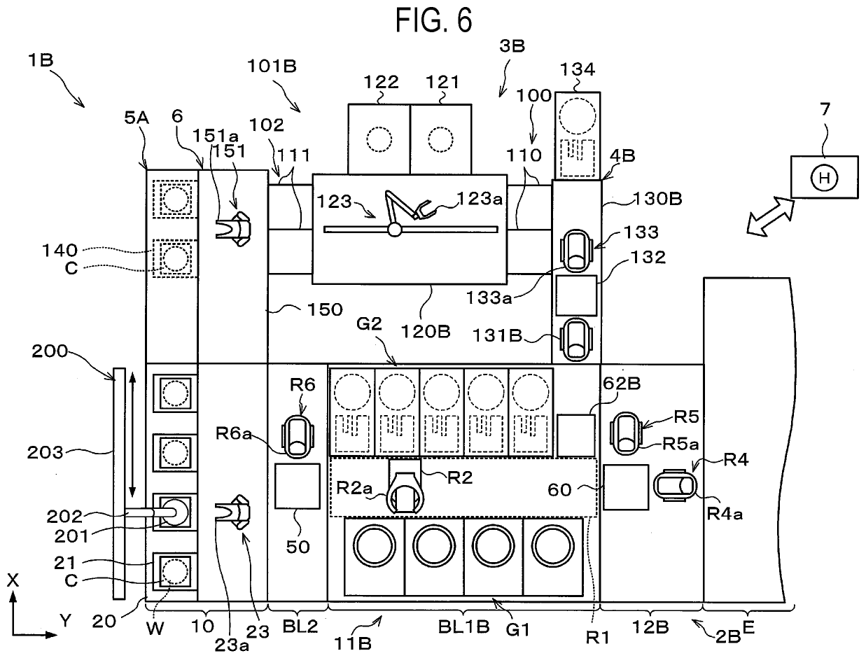

FIG. 6 is a view illustrating another example of the first transfer system.

The first transfer system 4 in the example illustrated in FIG. 1 and the like has the transfer path 130 at the position adjacent to the interface station 12 in the depth direction (the X direction in the figure). That is, a connection destination of the transfer path 130 to the wet processing system 2 is the interface station 12, and as a transfer of the wafer W to the wet processing system 2, the first transfer system 4 transfers the wafer W to the interface station 12. Alternatively, as illustrated in FIG. 6, a first transfer system 4B may have a transfer path 130B at a position adjacent to a processing block BL1B in the depth direction (the X direction in the figure). That is, a connection destination of the transfer path 130B to a wet processing system 2B is the processing block BL1B, and as a transfer of a wafer W to the wet processing system 2B, the first transfer system 4B transfers the wafer W to the processing block BL1B.

In this case, in a wafer processing system 1B, a delivery apparatus 62B is provided in the processing block BL1B for delivery between the first transfer system 4B and the wet processing system 2B. Specifically, the delivery apparatus 62B is located, for example, at a position adjacent to the rear side (the positive side in the X direction in the figure) of the transfer region R1 in the processing block BL1B and at a position of an end of the transfer region R1 on a side of an interface station 12B (the positive side in the Y direction in the figure).

In addition, in this case, at least a part of the transfer apparatuses R2 in the processing block BL1B can transfer the wafer W to the delivery apparatus 62B. In addition, in this case, a shuttle transfer apparatus 131B transfers the wafer W between the delivery apparatus 62B and the delivery apparatus 132 in the processing block BL1B.

The wafer processing system 1B in FIG. 6 is appropriately used when the wafer W, which has been subjected to heat treatment in the heat treatment apparatus 40 after the wet development process, is subjected to the dry development process in the processing apparatus 121 of a dry processing system 3B.

In addition, the wafer processing system 1B in FIG. 6 is appropriately used when the heat treatment apparatus 40 is shared between heat treatment for the wet development process and heat treatment for the dry development process. When the heat treatment apparatus 40 is shared as described above, the heat treatment apparatus 134 may be omitted. Omitting the heat treatment apparatus 134 is advantageous in terms of cost. In addition, in the wafer processing system 1B of FIG. 6, in a case where the heat treatment apparatus 40 is shared as described above, when the wafer W is transferred from a region where the heat treatment apparatus 40 is provided, i.e., a heat treatment region, to the dry processing system 3B, it is possible to immediately transfer the wafer W from the delivery apparatus 62B located in the heat treatment region without passing through the interface station 12B or delivery block BL2 adjacent to the heat treatment region. Therefore, since fewer transfer apparatuses are used when transferring the wafer W from the heat treatment region to the dry processing system 3B, another wafer W can be transferred at the same time. In addition, it is possible to reduce a risk of duplication of transfer apparatuses between transferring the wafer W for processes and transferring another wafer W.

In addition, in the case of the example illustrated in FIG. 6, the transfer apparatus R5 in the interface station 12B transfers the wafer W between the plurality of delivery apparatuses 61 of the delivery tower 60. In addition, in this case, a processing station 101B of the dry processing system 3B may have fewer processing apparatuses 121 and post-processing apparatuses 122 than the processing station 101 of FIG. 1 and the like, and a width (a length in the Y direction in the figure) of a vacuum transfer chamber 120B may be short.

### <Another Example of Wet Processing System and Example 1 of Second Transfer System>

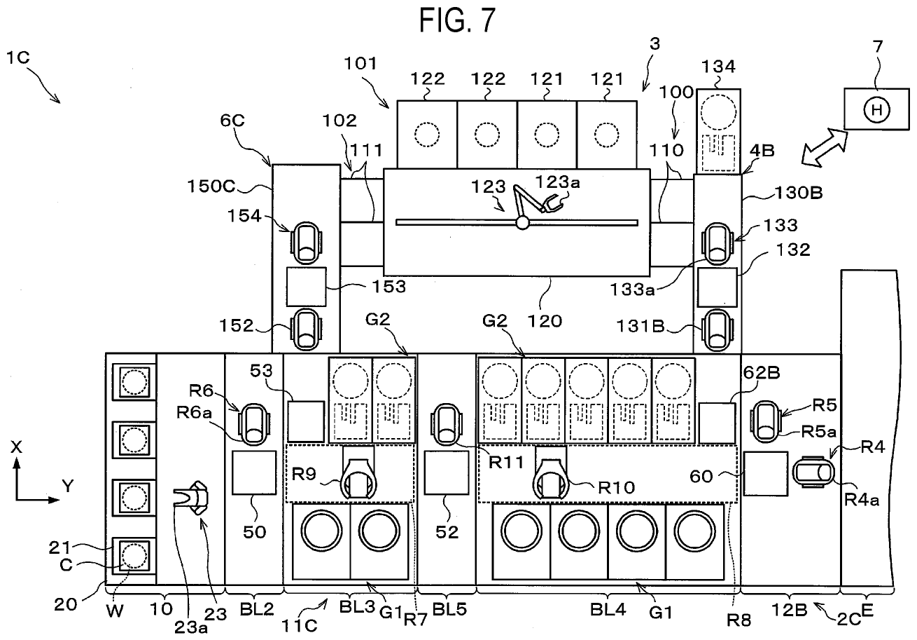

FIG. 7 is a view illustrating another example of the wet processing system and the second transfer system.

In the above-described examples, the number of processing blocks BL1, BL1A, or BL1B of the processing station 11, 11A, or 11B of the wet processing system 2, 2A, or 2B is one. In contrast, in a wet processing system 2C of FIG. 7, a plurality of (two in the example of the figure) processing blocks BL3 and BL4 is arranged in a processing station 11C along the width direction (the Y direction in the figure) with a relay block BL5 interposed therebetween. The processing block BL3 is located on a side of the cassette station 10, and the processing block BL4 is located on a side of the interface station 12B.

The processing blocks BL3 and BL4 are each configured to be substantially similar to the processing block BL1 illustrated in FIG. 1 and the like. Specifically, each of the processing blocks BL3 and BLA has, for example, the first block G1 on the front side (the negative side in the X direction in the figure). In the first block G1, the plurality of development apparatuses 30 and the plurality of resist coating apparatuses 31 are arranged side by side along the width direction (the Y direction in the figure). In addition, each of the processing blocks BL3 and BL4 has, for example, the second block G2 on the rear side (the positive side in the X direction in the figure). In the second block G2, the plurality of heat treatment apparatuses 40 is arranged side by side in the vertical direction and the width direction (the Y direction in the figure).

In addition, the number of development apparatuses 30 arranged side by side in the width direction may be different or the same between the processing block BL3 and the processing block BLA. The same applies to the resist coating apparatuses 31 and the heat treatment apparatuses 40.

In the present example, the delivery apparatus 62B is provided in the processing block BL4 for delivery between the first transfer system 4B and the wet processing system 2B. Specifically, the delivery apparatus 62B is located, for example, at a position adjacent to the rear side (the positive side in the X direction in the figure) of a transfer region R8, which will be described later, in the processing block BL4 and at a position of an end of the transfer region R8 on a side of the interface station 12B (the positive side in the Y direction in the figure).

In addition, the processing blocks BL3 and BL4 are respectively provided with transfer region R7 and R8 extending in the width direction between the first block G1 and the processing block BL3 and between the second block G2 and the processing block BL4. Transfer apparatuses R9 and R10 that transfer the wafer W are disposed in the transfer regions R7 and R8, respectively.

The transfer apparatus R9 can transfer the wafer W to the surrounding liquid processing apparatuses, the heat treatment apparatuses 40, a delivery apparatus 53 (described later), the delivery apparatuses 51 of the delivery tower 50, and delivery apparatuses of a delivery tower 52 (described later). The transfer apparatus R10 can transfer the wafer W to the surrounding liquid processing apparatuses, the heat treatment apparatuses 40, the delivery apparatus 62B, the delivery apparatuses of the delivery tower 52 (described later), and the delivery apparatuses 61 of the delivery tower 60.

The delivery tower 52 is provided in a center portion of the relay block BL5 in the depth direction (the X direction in the figure). Specifically, the delivery tower 52 is provided in a portion of the relay block BL5 between the transfer region R7 of the processing block BL3 and the transfer region R8 of the processing block BL4. The delivery tower 52 is provided with a plurality of delivery apparatuses (not illustrated) to overlap with one another in the vertical direction. A transfer apparatus R11 is provided on the rear side (the positive side in the X direction in the figure) of the delivery tower 52. The transfer apparatus R11 transfers the wafer W between the plurality of delivery apparatuses of the delivery tower 52.

In addition, the second transfer system 6 in the example illustrated in FIG. 1 and the like transfers the wafer W between the dry processing system 3 and the stage 5. With this configuration, the wafer W after the dry development process is returned to the cassette C on the stage 5. Alternatively, as illustrated in FIG. 7, a second transfer system 6C may transfer the wafer W between the dry processing system 3 and the wet processing system 2C. Specifically, the second transfer system 6C may transfer the wafer W between the dry processing system 3 and the processing block BL3 of the wet processing system 2C. With this configuration, the wafer W after the dry development process may be returned to the cassette C on the stage 20.

In this case, in the wafer processing system 1C, the stage 5 is omitted, and instead, for example, the delivery apparatus 53 is provided in the processing block BL3. Specifically, the delivery apparatus 53 is located, for example, at a position adjacent to the rear side (the positive side in the X direction in the figure) of the transfer region R7 in the processing block BL3 and at a position of an end of the transfer region R7 on a side of the cassette station 10 (the negative side in the Y direction in the figure).

In addition, in this case, a transfer path 150C of the second transfer system 6C is provided at a position adjacent to the processing block BL3. Specifically, the transfer path 150C is provided to extend in the depth direction (the X direction in the figure) from a portion of the processing block BL3 where the delivery apparatus 53 is provided. In the transfer path 150C, a shuttle transfer apparatus 152, a delivery apparatus 153, and a transfer apparatus 154 are provided in that order from a side of the processing block BL3 along the depth direction when viewed from above.

The shuttle transfer apparatus 152 transfers the wafer W between the delivery apparatus 53 and the delivery apparatus 153. The transfer apparatus 154 transfers the wafer W between the delivery apparatus 153 and the load-lock apparatus 110 of the dry processing system 3.

### <Another Example of Wet Processing System and Example 2 of Second Transfer System>

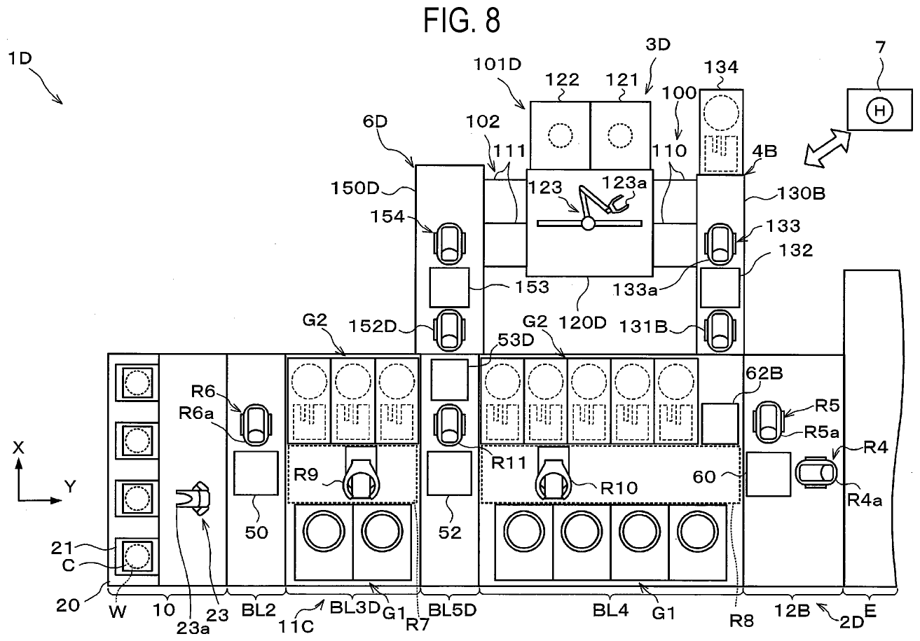

FIG. 8 is a view illustrating another example of the second transfer system.

The second transfer system 6C in the example illustrated in FIG. 7 and the like has the transfer path 150C at the position adjacent to the processing block BL3 in the depth direction (the X direction in the figure). That is, a connection destination of the transfer path 150C to the wet processing system 2C is the processing block BL3, and as a transfer of the wafer W to the wet processing system 2C, the first transfer system 4B transfers the wafer W to the processing block BL3. Alternatively, as illustrated in FIG. 8, a second transfer system 6D may have a transfer path 150D at a position adjacent to the relay block BL5D. That is, a connection destination of the transfer path 150D to a wet processing system 2D is the relay block BL5D, and as a transfer of the wafer W to the wet processing system 2D, the second transfer system 6D may transfer the wafer W to the relay block BL5D.

In this case, in a wafer processing system 1D, a delivery apparatus 53D is provided in the relay block BL5D for delivery between the second transfer system 6D and the wet processing system 2D. Specifically, the delivery apparatus 53D is provided, for example, at a position adjacent to the rear side (the positive side in the X direction in the figure) of the transfer apparatus R11 in the relay block BL5D.

In addition, in this case, the transfer apparatus R11 transfers the wafer W between the plurality of delivery apparatuses of the delivery tower 52 and the delivery apparatus 53D. In addition, in this case, a shuttle transfer apparatus 152D transfers the wafer W between the delivery apparatus 53D and the delivery apparatus 132 in the relay block BL5B.

In this case, the transfer apparatus R9 of the processing block BL3D transfers the wafer W between the surrounding liquid processing apparatuses, the heat treatment apparatuses 40, the delivery apparatuses 51 of the delivery tower 50, and the delivery apparatuses of the delivery tower 52. In this case, a processing station 101D of a dry processing system 3D may have fewer processing apparatuses 121 and post-processing apparatuses 122 than the processing station 101 of FIG. 1 and the like, and the width (the length in the Y direction in the figure) of a vacuum transfer chamber 120D may be shorter.

### <Another Example of Combination of Connection Destination of Transfer Path of First Transfer System and Connection Destination of Transfer Path of Second Transfer System>

When the connection destination of the transfer path of the first transfer system to the wet processing system is an interface station as in the examples of FIGS. 1 and 5, the connection destination of the transfer path of the second transfer system to the wet processing system may be a relay block as in the example of the figures.

In addition, when the connection destination of the transfer path of the first transfer system to the wet processing system is an interface station as in the examples of FIGS. 1 and 5, the connection destination of the transfer path of the second transfer system to the wet processing system may be a wet processing block as in the example of FIG. 7.

### <Another Example of Dry Processing System>

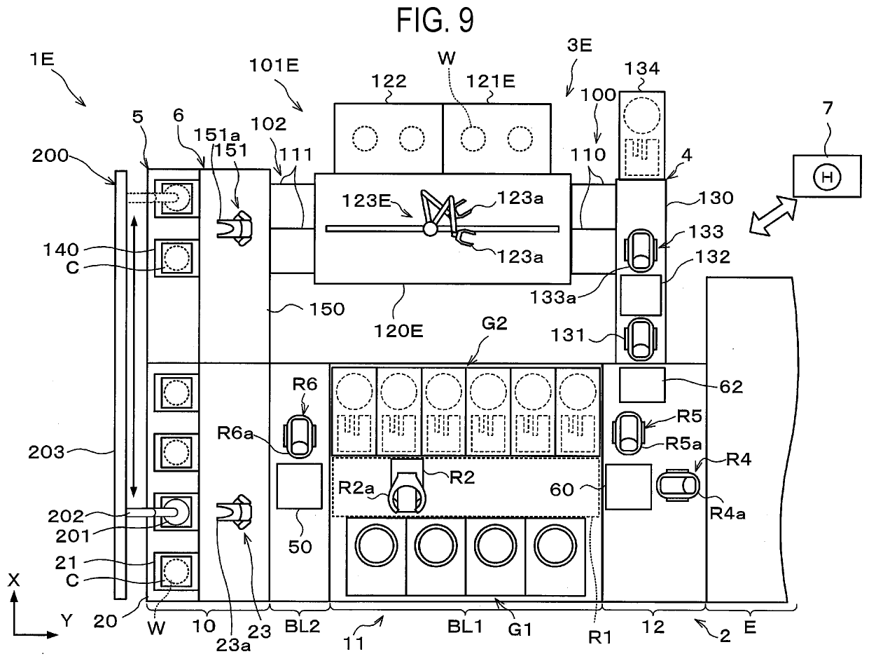

FIG. 9 is a view illustrating another example of the dry processing system.

In the examples illustrated in FIG. 1 and the like, in both the development process by the development apparatus 30, which performs the development process in the wet processing system 2, and the processing apparatus 121 that performs the development process in the dry processing system 3, the wafer W is processed in a sheet-by-sheet manner. Alternatively, as illustrated in FIG. 9, a processing apparatus 121E, which performs a dry development process, may process a plurality of (e.g., two) wafers W at once. That is, the processing apparatus 121E may be configured to be capable of processing a plurality of (e.g., two) wafers W at once. Specifically, for example, the processing apparatus 121E may be provided with a plurality of supports, each of which supports the wafer W, in one processing container configured to be capable of being depressurized.

In this case, the post-processing apparatus 122 may also be configured to be capable of processing a plurality of (e.g., two) wafers W at once.

In addition, in this case, in a processing station 101E of a dry processing system 3E of a wafer processing system 1E, a transfer apparatus 123E provided in a vacuum transfer chamber 120E may be configured to be capable of transferring a plurality of (e.g., two) wafers W at once. Specifically, for example, the transfer apparatus 123E may have a plurality of (e.g., two) transfer arms 123a each of which holds the wafer W.

### Second Embodiment

### <Wafer Processing System>

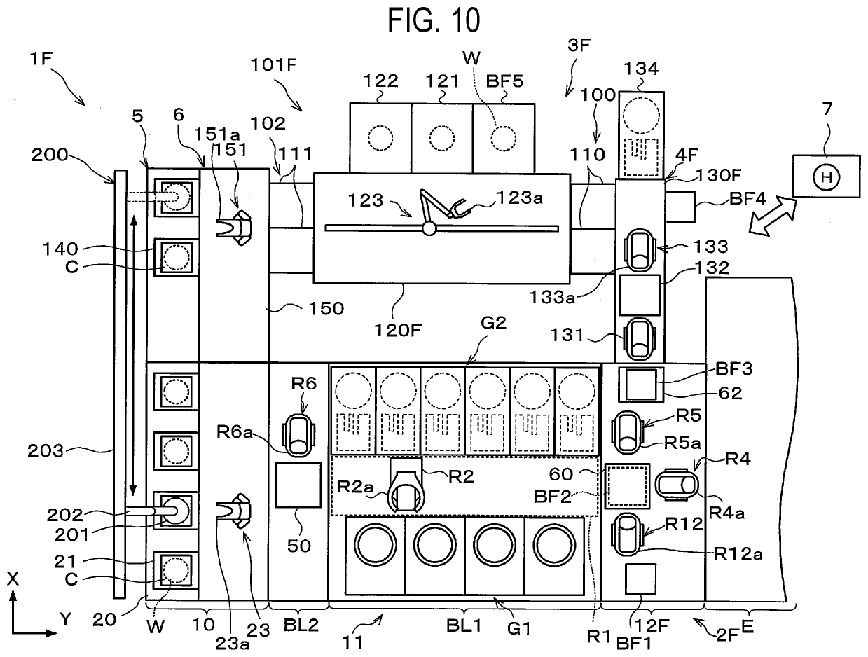

FIG. 10 is an explanatory view schematically illustrating an internal configuration of a wafer processing system as a substrate processing system according to a second embodiment.

In order to suppress variations in transfer time among wafers W, a timing is set such that wafers W loaded into the wafer processing system from the cassette C placed on the common stage 20 wait for transfer in the wafer processing system. In a case where a metal-containing resist is used as a resist, or the like, when an inter-process time from a resist film formation process to the PEB process, i.e., a delay time after the exposure process, is prolonged and the wafer W is made to wait for transfer in atmospheric atmosphere, a desired resist pattern may not be obtained due to influence of moisture in atmospheric atmosphere or the like.

Therefore, a wafer processing system 1F in FIG. 10 is provided with buffers BF1 to BF5. The buffers BF1 to BF5 are portions where the wafer W loaded into the wafer processing system 1F from the cassette C placed on the common stage 20 waits for being transferred for a subsequent process. Specifically, the buffers BF1 to BF5 are portions where the wafer W waits for being transferred for processing subsequent to the resist film formation process and prior to the development process.

The buffers BF1 to BF5 have a low-moisture atmosphere in which there is less moisture than atmospheric atmosphere. Specifically, the buffers BF1 to BF4 are gas buffers, each having an interior that becomes an inert gas atmosphere containing nitrogen gas or the like. The buffer BF5 is a vacuum buffer having an interior that becomes a vacuum atmosphere (reduced pressure atmosphere).

The buffer BF1 is provided on the front side (the negative side in the X direction in the figure) of an interface station 12F of a wet processing system 2F. When the exposure apparatus E performs the exposure process by an immersion method, a pre-exposure cleaning apparatus (not illustrated) is provided on the front side of the interface station 12F. In this case, the buffer BF1 is provided, for example, to be vertically stacked with the pre-exposure cleaning apparatus. The pre-exposure cleaning apparatus cleans a rear surface of the wafer W before exposure by the exposure apparatus E. A transfer apparatus R12 is provided for the buffer BF1. Specifically, the transfer apparatus R12 is provided between the delivery tower 60 and the buffer BF1 and includes, for example, a transfer arm R12a that is movable vertically and around the vertical axis. The transfer apparatus R12 can hold the wafer W on the transfer arm R12a and transfer the wafer W between apparatuses in the delivery tower 60 (a plurality of delivery apparatuses 61 and the buffer BF2) and the buffer BF1.

The buffer BF2 is provided in the delivery tower 60 of the interface station 12F. For example, the buffer BF2 is configured such that among the transfer apparatuses R2, R4, R5, and R12, only the transfer arm R12a of the transfer apparatus R12 can enter into the buffer BF2. Specifically, the buffer BF2 has a surface facing the transfer apparatus R2 (on the negative side in the Y direction in the figure), a surface facing the transfer apparatus R4 (on the positive side in the Y direction in the figure), and a surface facing the transfer apparatus R5 (on the positive side in the X direction in the figure), which are closed by walls (not illustrated), and only a surface facing the transfer apparatus R12 (on the negative side in the X direction in the figure) is open. In the buffer BF2, an inert gas such as nitrogen gas is supplied from a side of the transfer apparatus R5 toward the transfer apparatus R12. Thus, a unidirectional flow of the inert gas flowing along the surface of the wafer W accommodated in the buffer BF2 is formed, and an interior of the buffer BF2 becomes an atmosphere of the inert gas.

The buffer BF3 is provided on the rear side (the positive side in the X direction in the figure) of the interface station 12F, for example, to be stacked vertically with the delivery apparatus 62. When the exposure apparatus E performs the exposure process by an immersion method, a post-exposure cleaning apparatus (not illustrated) is provided on the rear side of the interface station 12F. In this case, the buffer BF3 is provided, for example, to be vertically stacked with the post-exposure cleaning apparatus. In addition, the post-exposure cleaning apparatus cleans the wafer W after exposure. The wafer W is transferred to the buffer BF3 by, for example, the transfer apparatus R5.

The buffer BF4 is provided in a first transfer system 4F. Specifically, the buffer BF4 is provided, for example, to be connected to a transfer path 130F on a side of the exposure apparatus E (the positive side in the Y direction in the figure). The wafer W is transferred to the buffer BF4 by, for example, the transfer apparatus 133.

The buffer BF5 is provided in a processing station 101F of the dry processing system 3F. Specifically, the buffer BF5 is connected to a vacuum transfer chamber 120F and provided to be aligned with the processing apparatus 121 and the post-processing apparatus 122 along the width direction (the Y direction in the figure). The wafer W is transferred to the buffer BF5 by the transfer apparatus 123.

Some of the buffers BF1 to BF5 may be omitted.

In addition, instead of at least one of the buffers BF1 to BF4 or in addition to the buffers BF1 to BF4, when the heat treatment apparatuses 40 and 134 have both a region for heating the wafer W with a hot plate and a cooling region for cooling the wafer W after heating, the cooling region of any of the heat treatment apparatuses 40 and 134 may serve as a gas buffer. Specifically, in addition to a cooling plate on which the wafer W is placed, a lid may be provided in the cooling region of the heat treatment apparatuses 40 and 134 to cover the wafer W placed on the cooling plate, a periphery of the wafer W may be covered by the cooling plate and the lid, and an inert gas may be supplied to a space between the cooling plate and the lid. In this case, the inert gas is supplied to the space, for example, via the lid.

In addition, the load-lock apparatus 110 may be used as a vacuum buffer instead of or in addition to the buffer BF5. In this case, a plurality of load-lock apparatuses 110 may be provided, and the plurality of load-lock apparatuses may be provided side by side, for example, in at least one of the vertical direction and the depth direction (the X direction in the figure).

In the case of the wafer processing system 1F in FIG. 10, the control device 7 performs control such that the wafer processing system 1F performs a process of making the wafer W loaded into the wafer processing system 1F wait and the wet or dry development process after the process of making the wafer W wait.

Specifically, for example, the control device 7 performs control such that the wafer W scheduled to be processed in the development apparatus 30 that performs the wet developing process waits in a gas buffer such as the buffer BF1, and the wafer W scheduled to be processed in the processing apparatus 121 that performs the dry developing process waits in a vacuum buffer such as the buffer BF5.

In addition, in the process of making the wafer W scheduled to be processed by the processing apparatus 121 that performs the dry development process wait, when another wafer W is accommodated in the vacuum buffer, the control device 7 performs control such that the wafer W scheduled to be processed by the processing apparatus 121 waits in the gas buffer.

Specifically, when another wafer W is accommodated in the vacuum buffer as described above, the control device 7 performs control such that the wafer W scheduled to be processed by the processing apparatus 121 waits in a gas buffer set as a buffer upstream of the vacuum buffer.

In addition, the buffer BF1 is used, for example, for the wafer W after the PAB process and before the exposure process. The buffer BF2 is used, for example, for the wafer W after the exposure process and before the PEB process by the heat treatment apparatus 40. The buffer BF3 is used, for example, for the wafer W after the exposure process and before the PEB process by the heat treatment apparatus 134 or for the wafer W after the PEB process by the heat treatment apparatus 40. The buffer BF4 is used, for example, for the wafer W after the exposure process and before the PEB process by the heat treatment apparatus 134 or for the wafer after the PEB process by the heat treatment apparatus 134. In addition, when the cooling region of the heat treatment apparatus 40 is used as the gas buffer, the gas buffer is used for the wafer after the PAB process by the heat treatment apparatus 40 and before the exposure process, or for a wafer W after the PEB process by the heat treatment apparatus 40. In addition, when the cooling region of the heat treatment apparatus 134 is used as the gas buffer, the gas buffer is used for the wafer W after the PEB process by the heat treatment apparatus 134.

As described above, the buffers BF1 to BF5 are portions where the wafer W waits for being transferred for processing subsequent to the resist film formation process and prior to the development process.

### Third Embodiment

### <Wafer Processing System>

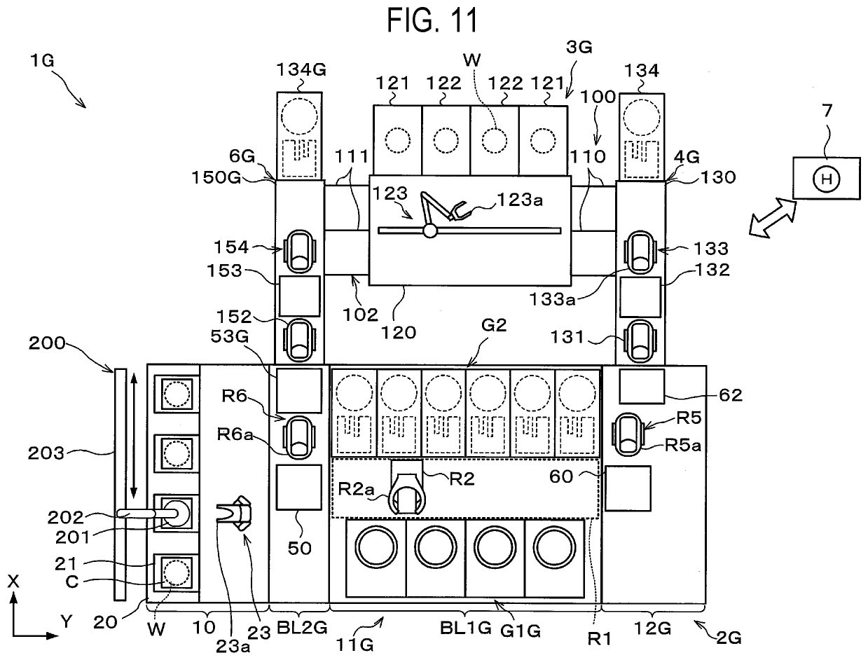

FIG. 11 is an explanatory view schematically illustrating an internal configuration of a wafer processing system as a substrate processing system according to a third embodiment.

In the above-described examples, the wafer processing system is connected to the exposure apparatus E and performs both the resist film formation process and the development process. In contrast, a wafer processing system 1G in FIG. 11 is not connected to the exposure apparatus E and performs only one of the resist film formation process and the development process, specifically, only the development process. The wafer processing system 1G may perform heat treatment such as the PEB process in addition to either the resist film formation process or the development process.

The wafer processing system 1G includes a wet processing system 2G, a dry processing system 3G, a first transfer system 4G, and a second transfer system 6G.

In addition to the above-described cassette station 10 and cassette transfer apparatus 200, the wet processing system 2G includes a processing station 11G and a relay station 12G.

The processing station 11G has a processing block BL1G on a side of the relay station 12G and a delivery block BL2G on a side of the cassette station 10.

The processing block BL1G has the above-described second block G2 on the rear side (the positive side in the X direction in the figure), and has a first block G1G on the front side (the negative side in the X direction in the figure).

The above-described first block G1 is provided with both the development apparatus 30 and the resist coating apparatus 31, whereas the first block G1G is provided with, for example, only the development apparatus 30. A plurality of development apparatuses 30 is arranged in the first block G1G, for example, in each of the depth direction and the vertical direction.

The delivery block BL2G is provided with the delivery tower 50 and the transfer apparatus R6, similar to the above-described delivery block BL2. In addition, the delivery block BL2G is provided with a delivery apparatus 53G for delivery between the second transfer system 6G and the wet processing system 2G. Specifically, the delivery apparatus 53G is provided, for example, at a position adjacent to the rear side (the positive side in the X direction in the figure) of the transfer apparatus R6 in the delivery block BL2G.

In the present embodiment, the transfer apparatus R6 of the delivery block BL2G transfers the wafer W between the plurality of delivery apparatuses 51 of the delivery tower 50 and the delivery apparatus 53G.

The relay station 12G is provided on a side of the processing station 11G opposite to a side of the cassette station 10, and delivers the wafer W between the processing block BL1G of the processing station 11G and the first transfer system 4G.

In addition, the relay station 12G is provided with the delivery tower 60, the delivery apparatus 62, and the transfer apparatus R5, similar to the above-described interface station 12.

The dry processing system 3G has a processing station 101G in addition to the first and second load-lock stations 100 and 102.

The processing station 101G includes the vacuum transfer chamber 120, the processing apparatuses 121, and the post-processing apparatuses 122, similar to the above-described processing station 101. However, the processing station 101G differs from the processing station 101 in the arrangement of the processing apparatuses 121 and the post-processing apparatuses 122. In the processing station 101, the processing apparatus 121, the processing apparatus 121, the post-processing apparatus 122, and the post-processing apparatus 122 are arranged in that order from the side of the cassette station 10 in the width direction (the Y direction in the figure). In contrast, in the processing station 101G, the processing apparatus 121, the post-processing apparatus 122, the post-processing apparatus 122, and the processing apparatus 121 are arranged in that order from the side of the cassette station 10 in the width direction (the Y direction in the figure).

The first transfer system 4G is configured to be similar to the above-described first transfer system 4.

In the second transfer system 6G, a connection destination of a transfer path 150G to the wet processing system 2G is the delivery block BL2G, and as a transfer of the wafer W to the wet processing system 2G, the second transfer system 6G transfers the wafer W to the delivery block BL2G. The transfer path 150G is provided to extend in the depth direction (the X direction in the figure) from a portion of the delivery block BL2G where the delivery apparatus 53G is provided. In the transfer path 150G, the shuttle transfer apparatus 152, the delivery apparatus 153, and the transfer apparatus 154 are provided in that order from a side of the delivery block BL2G side along the depth direction when viewed from above.

In this case, the shuttle transfer apparatus 152 transfers the wafer W between the delivery apparatus 53G and the delivery apparatus 153.

In addition, the second transfer system 6G may be provided with a heat treatment apparatus 134G similar to the heat treatment apparatus 40.

### Processing Example 1 by Wafer Processing System 1G

Next, a processing example by the wafer processing system 1G will be described.

When only the dry development process is performed, for example, the wafer W after the exposure process and before the PEB process is transferred in the following order.

Cassette C on stage 20→delivery tower 52→delivery apparatus 53G→delivery apparatus 153→heat treatment apparatus 134G→load-lock apparatus 111→processing apparatus 121 on side of cassette station 10→post-processing process 122 on side of cassette station 10

Accordingly, the wafer W after the exposure process and before the PEB process is sequentially subjected to the PEB process, the dry development process, and the heat treatment.

Thereafter, the wafer W is transferred in the following order and returned to the cassette C on the stage 20. Load-lock apparatus 111→delivery apparatus 153→delivery apparatus 53G→delivery tower 52→cassette C on stage 20

### Processing Example 2 by Wafer Processing System 1G

When only the wet development process is performed by using the wafer processing system 1G, for example, the wafer W after the exposure process and before the PEB process is transferred in the following order.

Cassette C on stage 20→delivery tower 52→heat treatment apparatus 40→development apparatus 30

Accordingly, the PEB process and the wet development process are sequentially performed on the wafer W after the exposure process and before the PEB process.

Thereafter, the wafer W is returned to the cassette C on the stage 20 via the delivery tower 52.

### Processing Example 3 by Wafer Processing System 1G

When the wet development process and the dry development process are performed on one wafer W in that order by the wafer processing system 1G, for example, the wafer W after the exposure process and before the PEB process is first transferred in the following order.

Cassette C on stage 20→delivery tower 52→heat treatment apparatus 40→development apparatus 30

Accordingly, a first PEB process and the wet development process are sequentially performed on the wafer W after the exposure process and before the PEB process.

Subsequently, the wafer W is transferred in the following order.

Delivery tower 60→delivery apparatus 62→delivery apparatus 132→heat treatment apparatus 134→load-lock apparatus 110→processing apparatus 121 on side of relay station 12G

Accordingly, a second PEB process, the dry development process, and the heat treatment are sequentially performed on the wafer W after the wet development process.

Thereafter, the wafer W is transferred in the following order and returned to the cassette C on the stage 20. Load-lock apparatus 111→delivery apparatus 153→delivery apparatus 53G→delivery tower 52→cassette C on stage 20

### <Modification of Wafer Processing System 1G>

The wafer processing system 1G may include an auxiliary processing apparatus (not illustrated) that additionally performs an auxiliary process on the wafer W. The auxiliary process is, for example, a UV irradiation process, an inspection process (specifically, an imaging process for inspection), or the like. For example, the auxiliary process apparatus is provided in each of the first transfer system 4G and the second transfer system 6G. In addition, the auxiliary process is performed, for example, after the post-processing by the post-processing apparatus 122.

In addition, the wafer processing system 1G may include a gas buffer (not illustrated) similar to the above-described buffer BF2. The gas buffer is provided, for example, in each of the delivery tower 50 and the delivery tower 60. In addition, in the transfer space including the delivery tower 50 and the delivery tower 60, an entire portion other than a portion having a vacuum atmosphere may be made to have an atmosphere of an inert gas such as nitrogen gas.

### <Other Modifications>

The heat treatment apparatus 134 of the first transfer system may be provided at a position that overlaps with the transfer path of the first transfer system when viewed from above. Specifically, the entire heat treatment apparatus 134 of the first transfer system may be provided at a position that overlaps with the transfer path of the first transfer system when viewed from above. More specifically, the heat treatment apparatus 134 of the first transfer system 4 may be provided at a position that overlaps with the shuttle transfer apparatus 131 and the delivery apparatus 132 when viewed from above.

Accordingly, a floor area occupied by the wafer processing system can be reduced.

The same applies to the heat treatment apparatus 134G of the second transfer system 6G.

In addition, in the above-described examples, the common stage 20 is provided for the wet processing system, but the common stage 20 may be provided for the dry processing system.

In the above-described examples, processes performed in a wet manner by the wet processing system and in a dry manner by the dry processing system have been described as the development process, but it is sufficient that the processes are processes for photolithography, such as a process of forming a film for photolithography or a process of cleaning the wafer W. In addition, in the wafer processing system connected to the exposure apparatus E, in the case of the development process, the wafer W moves in the dry processing system from the side of the exposure apparatus E toward the common stage 20. However, in a case of the film formation process, the wafer W moves in the dry processing system from the side of the common stage 20 side toward the exposure apparatus E.

In the above-described examples, the post-processing performed by the post-processing apparatus 122 is a heating process, but may also be a coating process of covering a surface of the wafer W with a predetermined film. By the coating process, the resist pattern can be reinforced. In addition, by the coating process, it is possible to suppress a corrosive gas from being released from the wafer W during transfer.

In addition, in the above-described examples, the post-processing for the dry development process was performed on the wafer W under a vacuum atmosphere, but the post-processing may also be performed under atmospheric pressure atmosphere. Accordingly, the wafer processing system can be miniaturized.

It is to be considered that the embodiments disclosed herein are exemplary in all respects and not restrictive. Various types of omissions, replacements, and changes may be made to the above-described embodiments without departing from the scope and spirit of the appended claims. For example, the constituent features of the above-described embodiments may be combined arbitrarily. From the arbitrary combination, the actions and advantageous effects of respective constituent features of the combination are obtained naturally, and other actions and advantageous effects that will be apparent to those skilled in the art from the description of the present specification are obtained.

In addition, the effects described in the present specification are merely explanatory or exemplary, and are not limiting. In other words, the technology according to the present disclosure may have other effects that are apparent to those skilled in the art from the description of the present specification, in addition to or in place of the above-described effects.

The following configuration examples also fall within the technical scope of the present disclosure.

(1) A substrate processing system that performs substrate processing, wherein the substrate processing is any processing from forming a resist film on a substrate to developing the resist film after exposure, the substrate processing system including:
a first processing system having one of a wet processing apparatus configured to perform the substrate processing in a wet manner and a dry processing apparatus configured to perform the substrate processing in a dry manner; and
a second processing system having the other one of the wet processing apparatus and the dry processing apparatus,
wherein the first processing system includes a common stage that is common to the first processing system and the second processing system,
wherein the common stage is configured to place a container, which is configured to accommodate a plurality of substrates before being subjected to the substrate processing, on the common stage,
wherein the substrate processing system further includes:
   a first transfer system configured to transfer the substrates between the first processing system and the second processing system; and
   a second transfer system provided separately from the first transfer system and connected to at least the second processing system, and
wherein the second transfer system is configured to transfer the substrates between the first processing system and the second processing system, or between another stage, which is provided separately from the common stage and on which the container is placed, and the second processing system.

(2) The substrate processing system of item (1), further including a buffer in which a substrate loaded into the substrate processing system from the container placed on the common stage waits for transfer,
wherein an interior of the buffer is a low-moisture atmosphere containing less moisture than an atmospheric atmosphere.

(3) The substrate processing system of item (2), further including a controller,
wherein the buffer includes a gas buffer having an interior of an inert gas atmosphere, and a vacuum buffer having an interior of a vacuum atmosphere interior, and
wherein the controller is configured to perform a control to make a substrate scheduled to be processed by the wet processing apparatus wait in the gas buffer, and to make a substrate scheduled to be processed by the dry processing apparatus wait in the vacuum buffer.

(4) The substrate processing system of item (3), wherein the controller is configured to perform a control such that in making the substrate scheduled to be processed in the dry processing apparatus wait, when another substrate is accommodated in the vacuum buffer, the substrate scheduled to be processed in the dry processing apparatus waits in the gas buffer.

(5) The substrate processing system of any one of items (1) to (4), wherein the wet processing apparatus is configured to process the substrates in a sheet-by-sheet manner, and
wherein the dry processing apparatus is configured to process the substrates at once.

(6) The substrate processing system of any one of items (1) to (5), wherein each of the first transfer system and the second transfer system has a transfer path connected to the second processing system, and
wherein, among the first transfer system and the second transfer system, a system having the wet processing apparatus has an interior having a same pressure and a same atmosphere as the transfer path.

(7) The substrate processing system of any one of items (1) to (6), wherein the first processing system is connected to an exposure apparatus,
wherein the first processing system includes:
   a processing block provided with one of the wet processing apparatus and the dry processing apparatus; and
   an interface block configured to perform delivery of the substrates between the processing block and the exposure apparatus, and
wherein, as a transfer of the substrates to the first processing system, the first transfer system transfers the substrates to the interface block.

(8) The substrate processing system of any one of items (1) to (6), wherein the first processing system is connected to an exposure apparatus,
wherein the first processing system includes:
   a processing block provided with one of the wet processing apparatus and the dry processing apparatus; and
   an interface block configured to perform delivery of the substrates between the processing block and the exposure apparatus, and
wherein, as a transfer of the substrates to the first processing system, the first transfer system transfers the substrates to the processing block.

(9) The substrate processing system of any one of items (1) to (8), wherein the second transfer system transfers the substrates between the another stage and the second processing system, and
wherein the another stage is configured to be accessible by a container transfer apparatus that transfers the container to the common stage.

(10) The substrate processing system of any one of items (1) to (8), wherein the second transfer system transfers the substrates between the another stage and the second processing system, and
wherein the another stage is covered in a portion where the container is placed, and is spaced apart from the common stage.

(11) The substrate processing system of item (7) or (8), wherein the second transfer system transfers the substrates between the first processing system and the second processing system, and
wherein, as a transfer of the substrates to the first processing system, the second transfer system transfer the substrates to the processing block.

(12) The substrate processing system of item (7) or (8), wherein a plurality of processing blocks is provided along a width direction, along which the exposure apparatus and the substrate processing system are aligned, with a relay block interposed therebetween,
wherein the second transfer system transfers the substrates between the first processing system and the second processing system, and
wherein, as a transfer of the substrates to the first processing system, the second transfer system transfers the substrates to the relay block.

(13) A substrate processing method of performing substrate processing by using a substrate processing system,
wherein the substrate processing is any processing from forming a resist film on a substrate to developing the resist film after exposure,
wherein the substrate processing system includes:
   a first processing system having one of a wet processing apparatus configured to perform the substrate processing in a wet manner and a dry processing apparatus configured to perform the substrate processing in a dry manner; and
   a second processing system having the other one of the wet processing apparatus and the dry processing apparatus, and
   a buffer having an interior of a low-moisture atmosphere containing less moisture than atmospheric atmosphere, and
   wherein the substrate processing method includes:
      making the substrate loaded into the substrate processing system wait in the buffer; and
      performing the substrate processing in a wet or dry manner after the making the substrate wait.

According to the present disclosure, processes for photolithography other than an exposure process can be performed in both wet and dry manners in a relatively small space.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing system that performs substrate processing, wherein the substrate processing includes at least one of forming a resist film on a substrate or developing the resist film after exposure, the substrate processing system comprising:
a first processing system having one of a wet processing apparatus configured to perform the substrate processing in a wet manner and a dry processing apparatus configured to perform the substrate processing in a dry manner; and
a second processing system having the other one of the wet processing apparatus and the dry processing apparatus,
wherein the first processing system includes a common stage that is common to the first processing system and the second processing system,
wherein the common stage is configured to place a container, which is configured to accommodate a plurality of substrates before being subjected to the substrate processing, on the common stage,
wherein the substrate processing system further comprises:
a first transfer system configured to transfer the substrates between the first processing system and the second processing system; and
a second transfer system provided separately from the first transfer system and connected to at least the second processing system, and
wherein the second transfer system is configured to transfer the substrates between the first processing system and the second processing system, or between another stage, which is provided separately from the common stage and on which the container is placed, and the second processing system.

2. The substrate processing system of claim 1, further comprising a buffer in which a substrate loaded into the substrate processing system from the container placed on the common stage waits for transfer,
wherein an interior of the buffer is a low-moisture atmosphere containing less moisture than an atmospheric atmosphere.

3. The substrate processing system of claim 2, further comprising a controller,
wherein the buffer includes a gas buffer having an interior of an inert gas atmosphere, and a vacuum buffer having an interior of a vacuum atmosphere, and
wherein the controller is configured to perform a control to make a substrate scheduled to be processed by the wet processing apparatus wait in the gas buffer, and to make a substrate scheduled to be processed by the dry processing apparatus wait in the vacuum buffer.

4. The substrate processing system of claim 3, wherein the controller is further configured to perform a control such that in making the substrate scheduled to be processed in the dry processing apparatus wait, when another substrate is accommodated in the vacuum buffer, the substrate scheduled to be processed in the dry processing apparatus waits in the gas buffer.

5. The substrate processing system of claim 4, wherein the wet processing apparatus is configured to process the substrates in a sheet-by-sheet manner, and
wherein the dry processing apparatus is configured to process the substrates at once.

6. The substrate processing system of claim 4, wherein each of the first transfer system and the second transfer system has a transfer path connected to the second processing system, and
wherein, among the first transfer system and the second transfer system, a system having the wet processing apparatus has an interior having a same pressure and a same atmosphere as the transfer path.

7. The substrate processing system of claim 1, wherein the first processing system is connected to an exposure apparatus,
wherein the first processing system comprises:
a processing block provided with one of the wet processing apparatus and the dry processing apparatus; and
an interface block configured to perform delivery of the substrates between the processing block and the exposure apparatus, and
wherein, as a transfer of the substrates to the first processing system, the first transfer system transfers the substrates to the interface block.

8. The substrate processing system of claim 7, wherein the second transfer system transfers the substrates between the first processing system and the second processing system, and
wherein, as a transfer of the substrates to the first processing system, the second transfer system transfers the substrates to the processing block.

9. The substrate processing system of claim 7, wherein a plurality of processing blocks is provided along a width direction, along which the exposure apparatus and the substrate processing system are aligned, with a relay block interposed therebetween,
wherein the second transfer system transfers the substrates between the first processing system and the second processing system, and
wherein, as a transfer of the substrates to the first processing system, the second transfer system transfers the substrates to the relay block.

10. The substrate processing system of claim 1, wherein the first processing system is connected to an exposure apparatus,
wherein the first processing system comprises:
a processing block provided with one of the wet processing apparatus and the dry processing apparatus; and
an interface block configured to perform delivery of the substrates between the processing block and the exposure apparatus, and
wherein, as a transfer of the substrates to the first processing system, the first transfer system transfers the substrate to the processing block.

11. The substrate processing system of claim 10, wherein the second transfer system transfers the substrates between the first processing system and the second processing system, and
wherein, as a transfer of the substrates to the first processing system, the second transfer system transfers the substrates to the processing block.

12. The substrate processing system of claim 10, wherein a plurality of processing blocks is provided along a width direction, along which the exposure apparatus and the substrate processing system are aligned, with a relay block interposed therebetween,
wherein the second transfer system transfers the substrates between the first processing system and the second processing system, and
wherein, as a transfer of the substrates to the first processing system, the second transfer system transfers the substrates to the relay block.

13. The substrate processing system of claim 1, wherein the wet processing apparatus is configured to process the substrates in a sheet-by-sheet manner, and
wherein the dry processing apparatus is configured to process the substrates at once.

14. The substrate processing system of claim 1, wherein each of the first transfer system and the second transfer system has a transfer path connected to the second processing system, and
wherein, among the first transfer system and the second transfer system, a system having the wet processing apparatus has an interior having a same pressure and a same atmosphere as the transfer path.

15. The substrate processing system of claim 1, wherein the second transfer system transfers the substrates between the another stage and the second processing system, and
wherein the another stage is configured to be accessible by a container transfer apparatus that transfers the container to the common stage.

16. The substrate processing system of claim 1, wherein the second transfer system transfers the substrates between the another stage and the second processing system, and
wherein the another stage is covered in a portion where the container is placed, and is spaced apart from the common stage.

17. A substrate processing method of performing substrate processing by using a substrate processing system,
wherein the substrate processing includes at least one of forming a resist film on a substrate or developing the resist film after exposure,
wherein the substrate processing system comprises:
a first processing system having one of a wet processing apparatus configured to perform the substrate processing in a wet manner and a dry processing apparatus configured to perform the substrate processing in a dry manner;
a second processing system having the other one of the wet processing apparatus and the dry processing apparatus; and
a buffer having an interior of a low-moisture atmosphere that contains less moisture than atmospheric atmosphere, and
wherein the substrate processing method comprises:
making the substrate loaded into the substrate processing system wait in the buffer; and
performing the substrate processing in a wet or dry manner after the making the substrate wait.
